(19) United States
(12) Patent Application Publication
(10) Pub. No.: US 2026/0020380 A1
(43) Pub. Date: Jan. 15, 2026

(54) LIGHT EMITTING DIODE DEVICES WITH JUNCTION SPACERS AND ACTIVE METAL-SEMICONDUCTOR CONTACT

(71) Applicant: Lumileds LLC, San Jose, CA (US)

(72) Inventors: Toni Lopez, Vaals (NL); Erik William Young, San Jose, CA (US); Byung-Kwon Han, Santa Clara, CA (US); Costas Dimitropoulos, Redwood City, CA (US)

(73) Assignee: Lumileds LLC, San Jose, CA (US)

(21) Appl. No.: 18/994,789

(22) PCT Filed: Jul. 17, 2023
(86) PCT No.: PCT/US2023/027874

§ 371 Date: Jan. 15, 2025

Related U.S. Application Data
(60) Provisional application No. 63/391,949, filed on Jul. 25, 2022.

(51) Int. Cl. H10H 20/816; H10H 29/85

(52) U.S. Cl. CPC H10H 20/816; H10H 29/8506

(57) ABSTRACT

Described are light emitting diode (LED) arrays comprising a plurality of mesas defining pixels having sidewalls, each of the mesas comprising semiconductor layers having a total thickness, the semiconductor layers including an n-type layer, an active region, and a p-type layer. A plurality of junction spacers comprise a dielectric material conformal to a portion of the sidewalls, and span a longitudinal distance of greater than or equal to 20% of the thickness of the semiconductor layers. A plurality of cathodes comprising the n-contact material between each of the mesas provide optical isolation therebetween, and electrically contact an uninsulated portion of the n-type layer of each of the mesas along the sidewalls, the uninsulated portion of the n-type layer comprising a doped N-type material. A surface of the doped N-type material of the uninsulated portion of the n-layer is effective to provide an active metal-semiconductor contact.

### TECHNICAL FIELD

Embodiments of the disclosure generally relate to light emitting diode (LED) devices and methods of manufacturing the same. More particularly, embodiments are directed to light emitting diode devices that include junction spacers that extend deeply into metal trenches. The junction spacers access a doped region of an n-type layer. The junction spacers inhibit and/or prevent interactions of photons to the metal trenches. In one or more embodiments, a surface of the doped region of the n-type layer is effective to provide an active metal-semiconductor contact.

### BACKGROUND

A light emitting diode (LED) is a semiconductor light source that emits visible light when current flows through it. LEDs combine a p-type semiconductor with an n-type semiconductor. LEDs commonly use a III-V group compound semiconductor. A III-V group compound semiconductor provides stable operation at a higher temperature than devices that use other semiconductors. The III-V group compound is typically formed on a substrate formed of sapphire aluminum oxide (Al₂O₃), silicon (Si), or silicon carbide (SiC). For example, one or more III-nitride materials, such as GaN, can be epitaxially-grown on a substrate or wafer to prepare semiconductor layers. The substrate may remain as part of a final product, or may be removed during processing.

In-organic light emitting diodes (i-LEDs) have been widely used to create different types of displays, LED matrices and light engines including automotive adaptive headlights, augmented-, virtual-, mix-reality (AR/VR/MR) headsets, smart glasses and displays for mobile phones, smart watches, monitors and TVs. The individual LED pixels in these architectures could have an area of few square millimeters down to few square micrometers depending on the matrix or display size and its pixel per inch requirements. One common approach is to create a monolithic array of LED pixels on an epitaxial (EPI) wafer and later transfer and possibly hybridize these LED arrays to a backplane to control individual pixels.

One embodiment of such monolithic arrays utilizes metal (e.g., Al-based or Ag-based) side-contacts. These side contacts serve as an electrical cathode for each pixel and also provide reflective sidewalls in between the pixels to reduce light scattering and propagation in lateral directions. With this geometry, a metal grid is created in between pixels of an LED display or matrix. Such side contacts typically extend deep into a bottom of a trench in between the pixels formed by etching and/or segmenting the semiconductor (epitaxial) layers, and reach a surface of the substrate. Deep side contacts can be used to ensure low sheet and contact resistance for cathode contacts, and to optically separate each LED pixel so that there is not optical crosstalk, thereby maximize optical contrast. There is, however, a cost of optical absorption due to the limited reflectivity of the metal contact.

In some of these architectures, the substrate (e.g., sapphire, silicon) is removed after the LED array is attached to a backplane controller to enhance light extraction and beam profiling. A standard approach to remove a sapphire substrate is by a laser lift-off process where a laser beam is used to detach the substrate from the epitaxial layers (in this case, LED arrays grown on the substrate). Such methods could damage the side contacts, and such effects could also pose long-term reliability concerns. In addition, a problem with this approach is that the trench surface interface to the epitaxial layers must be a metal to form contact. Metals (typically used to make contact to n-type epi layer) are usually poor optical reflectors and hence extraction efficiency (ExE) can be limited by severe absorption in the cavity.

There remains a need for maximizing optical efficiency in designs of die/epi layout to create a composite cathode contact for micro-LEDs, Mini-LEDs and LED arrays with a side-contact cathode.

### SUMMARY

Embodiments of the disclosure are directed to light emitting diodes (LEDs) and light emitting diode (LED) arrays, including in particular individual LEDs having at least one characteristic dimension of less than or equal to 500 micrometers, the character dimension being selected from the group consisting of: height, width, depth, thickness, and combinations thereof.

Aspects provide light emitting diode (LED) s comprising: a plurality of semiconductor layers defining a pixel having a sidewall, the semiconductor layers having a total thickness, the semiconductor layers including an n-type layer, an active region, and a p-type layer; a current spreading layer disposed on the p-type layer; a junction spacer comprising a dielectric material conformal to a portion of the sidewall, and insulating: the current spreading layer, the p-type layer, the active region, and an insulated portion of the n-type layer from an n-contact material, the junction spacer spanning a longitudinal distance of greater than or equal to 20% of the thickness of the semiconductor layers; a cathode comprising the n-contact material electrically contacting an uninsulated portion of the n-type layer along the sidewall, the uninsulated portion of the n-type layer comprising a doped N-type material; and an anode comprising one or more p-contact materials in contact with the current spreading layer.

In an aspect, a light emitting diode (LED) array comprises: a plurality of mesas defining pixels having sidewalls, each of the mesas comprising semiconductor layers having a total thickness, the semiconductor layers including an n-type layer, an active region, and a p-type layer; a plurality of current spreading layers, each disposed on the p-type layer of each mesa; a plurality of junction spacers comprising a dielectric material conformal to a portion of the sidewalls, and insulating: the current spreading layer, the p-type layer, the active region, and an insulated portion of the n-type layer of each mesa from an n-contact material, the junction spacers spanning a longitudinal distance of greater than or equal to 20% of the thickness of the semiconductor layers; a plurality of cathodes comprising the n-contact material between each of the mesas, providing optical isolation therebetween, and electrically contacting an uninsulated portion of the n-type layer of each of the mesas along the sidewalls, the uninsulated portion of the n-type layer comprising a doped N-type material; and a plurality of anodes, each anode comprising one or more p-contact materials in contact with the current spreading layer.

Another aspect is: a light emitting diode (LED) array comprising: a plurality of mesas defining pixels having sidewalls, each of the mesas comprising semiconductor layers having a total thickness, the semiconductor layers including a first n-type template layer, a doped N-type layer constituting greater than or equal to 20% of the thickness of the semiconductor layers and having first and second portions, an active region, a second n-type template layer, and a p-type layer; a plurality of junction spacers comprising a dielectric material conformal to a portion of the sidewalls, and insulating a p-contact layer, the p-type layer, the active region, the second n-type template layer, and the second portion of the doped N-type layer from n-contact material, the junction spacers spanning a longitudinal distance of greater than or equal to 20% of the thickness of the semiconductor layers; a plurality of cathodes comprising the n-contact material between each of the mesas, providing optical isolation therebetween and electrically contacting the first portion of the doped N-type layer and the first n-type template layer of each of the mesas along the sidewalls; and a plurality of anodes, each anode comprising the p-contact layer and one or more p-contact materials, each p-contact layer being in contact with each of the p-type layers of the mesas.

In other aspects, a light emitting diode (LED) array comprises: a plurality of mesas defining pixels having sidewalls, each of the mesas comprising semiconductor layers having a total thickness, the semiconductor layers including an n-type layer, an active region, and a p-type layer; a plurality of current spreading layers, each disposed on the p-type layer of each mesa; a plurality of junction spacers comprising a dielectric material conformal to a portion of the sidewalls, and insulating the current spreading layer, the p-type layer, the active region, and an insulated portion of the n-type layer of each mesa from an n-contact material; a plurality of active metal-semiconductor contacts electrically contacting the n-contact material and comprising an uninsulated portion of the n-type layer of each of the mesas along the sidewalls, the uninsulated portion of the n-type layer comprising a doped N-type material; a plurality of cathodes comprising the n-contact material between each of the mesas, providing optical isolation therebetween; and a plurality of anodes, each anode comprising one or more p-contact materials in contact with the current spreading layer.

A further aspect is a method of manufacturing a light emitting diode (LED) device, the method comprising: growing a plurality of semiconductor layers including an n-type layer, an active region, and a p-type layer on a substrate; depositing a current spreading layer on the p-type layer; depositing a mesa dielectric material on the current spreading layer; etching the mesa dielectric material and forming inner spacers and deposing a p-contact layer; etching the current spreading layer, the p-type layer, the active region, and a portion of the n-type layer, to form openings; depositing a dielectric material conformally in the openings on exposed surfaces of the p-type layer, the active region, the portion of the n-type layer, the current spreading layer to form junction spacers that contact the current spreading layer, the inner spacers, the p-type layer, the active region, the portion of the n-type layer; etching a remaining portion of the n-type layer to expose a top surface of the substrate to form trenches and to expose a doped N-type material, and thereby preparing a plurality of mesas defining pixels having sidewalls, and each of the mesas comprising the semiconductor layers having a thickness; deposition of a hard mask material and forming anode sidewalls in the hard mask material, which with the top surface of the p-contact layer define hard mask openings; depositing an electrode metal on the substrate filling the trenches and the hard mask openings; and processing the substrate to remove excess electrode metal and to form an n-contact material providing optical isolation between each of the mesas, and electrically contacting the first portion of the doped N-type layer and the first n-type template layer of each of the mesas along the sidewalls, and to form a p-metal material in the hard mask openings.

Another aspect provides a method of emitting light from a light emitting diode (LED) device, the method comprising: applying power to the LED array of any array herein, the junction spacers being effective to inhibit interactions of photons with the n-contact material.

A further aspect is a display comprising: the light emitting diode (LED) array according to any embodiment herein affixed to a device substrate by anode metallization bumps.

Other aspects include automotive lighting arrangement comprising: any light emitting diode (LED) array disclosed herein mounted to a circuit board; a collimator element positioned to receive light from the LED array; and a lens attached to the collimator element to project light emitted from the collimator element.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 is a cross-sectional view of a portion of a light emitting diode (LED) array according to one or more embodiments;

FIG. 2 is the cross-sectional view of a portion of a light emitting diode (LED) array according to one or more embodiments further including anode metallization bumps;

FIG. 3 is a cross-sectional view of a portion of a light emitting diode (LED) array according to one or more embodiments;

FIG. 4 illustrates a top plan view of an exemplary display device according to one or more embodiments;

FIG. 5 schematically illustrates an exemplary display system comprising LED devices according to embodiments; and

FIG. 6 shows a block diagram of a visualization system according to one or more embodiments.

To facilitate understanding, identical reference numerals have been used, where possible, to designate identical elements that are common to the figures. The figures are not drawn to scale. For example, the heights and widths of the mesas are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN and alloys), metal alloys, and other conductive materials, metal phosphides (e.g., InP) depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed are also performed on an underlayer formed on the substrate, and the term “substrate surface” is intended to include such underlayer as the context indicates. Thus for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Reference to a micro-LED (uLED) means a light emitting diode having one or more characteristic dimensions (e.g., height, width, depth, thickness, etc. dimensions) of less than 100 micrometers. In one or embodiments, one or more dimensions of height, width, depth, thickness have values in a range of 1 to 100 micrometers, including all values and subranges therebetween.

LEDs capable of operation across the visible spectrum include Group III-V semiconductors, particularly binary, ternary, and quaternary alloys of gallium, aluminum, indium, and nitrogen, also referred to as III-nitride materials. Typically, Ill-nitride light emitting devices are fabricated by epitaxially growing a stack of semiconductor layers of different compositions and dopant concentrations on a growth substrate such as a sapphire, silicon carbide, Ill-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region. An LED die is a structure including a substrate and the stack of semiconductor layers.

The present disclosure details die/epi layouts to create a composite cathode contact for micro-LEDs, mini-LEDs and LED arrays with a side-contact cathode. Embodiments of composite cathode contacts herein improves optical performance of monolithically integrated micro-LED or LED arrays. The methods and embodiments disclosed herein are applicable to both phosphor-converted and direct-color LEDs where each individual pixel has an area ranging from few square micrometers (Micro-LEDs) to square millimeters (conventional LEDs).

Typically, in order to electrically isolate p-type and n-type layers (e.g., from metal in trenches between pixels), a dielectric layer (junction spacer) is used at trench sidewalls covering active region edges, and extending to a depth sufficient to etch away the active region so as to access some highly doped layers (e.g., doped N-layer) of the epi. Previously, this had corresponded to a small fraction of the epi thickness (e.g. ⅙).

The present disclosure utilizes this junction spacer to further transform it into a light-management layer, thus inhibiting and/or preventing light (e.g. photons) from interacting with the metal in the trenches over a wide area of the trench sidewalls. In one or more embodiments, the junction spacer comprises a material whose refractive index is lower than a refractive index of the semiconductor layers. In one or more embodiments, the junction spacer provides a total internal reflection (TIR) to increase side-wall reflectivity. In one or more embodiments, the junction spacer comprises a material whose refractive index is lower than a refractive index of the semiconductor layers, and provides a total internal reflection (TIR). Epi structures (e.g., semiconductor layers) herein are designed to accommodate a highly doped epi layer at a bottom of the junction spacer, the highly doped layer being present in higher proportions than in previous designs. The semiconductor layers are designed to include an n-type layer comprising a region of a doped n-type material among one or more regions of undoped or lesser-doped n-type material. In one or more embodiments, the region of the doped N-type material constitutes greater than or equal to 20% of the thickness of the semiconductor layers, including greater than or equal to 20% to less than or equal to 95%, and all values and subranges therebetween. Conventionally, doped N-type layers for contacts are deposited on top of a sufficiently thick (1-3 μm), unintentionally-doped (or undoped) defect-reducing semiconductor template layer (e.g., an n-type layer), which is grown on top of sapphire substrates. This is to grow high quality semiconductor materials suitable for good LED. To enable deeper sidewall metal contact, a portion (e.g., 50-100%) of unintentionally-doped (or undoped) semiconductor template layer was replaced with doped N-type layers.

Generally, arrays and devices herein comprise: LED/micro-LED EPI wafers grown on a patterned or planar substrates, in particular sapphire substrates, with modified n-doping profile characteristics; a metallic structure at pixel sidewalls that optically isolates pixels and serves as a composite cathode contact; and extended junction spacers, which inhibit and/or prevent light from interacting with the metallic structure over a wide area of the sidewalls. By design, a portion of a highly doped epi layer at a bottom of the junction spacers facilitates ohmic contact formation. Optional phosphor layers or encapsulant/protective layers or secondary optics layers can be created on top of LED pixels and composite metal grid/cathode (DBR).

In one or more embodiments, the junction spacers comprise a dielectric material. In one or more embodiments, the junction spacers comprise one or more dielectric materials. In one or more embodiments, the junction spacers comprise one or more dielectric materials selected from the group consisting of: silicon dioxide (SiO₂), aluminum oxide (Al₂O₃), silicon oxynitride (Si₂ON₂), and silicon nitride (Si₃N₄), and/or combinations thereof. In one or more embodiments, the junction spacers have a thickness greater than about 10 nm, or greater than about 20 nm, or greater than about 100 nm. In other embodiments, the junction spacers have a thickness in a range of from 10 nm to 500 nm.

In one or more embodiments, the junction spacers comprise a thin layer stack to form a distributed Bragg reflector (DBR) (interferometric filter) to increase light reflectivity with narrow or broadband characteristics. In one or more embodiments, the junction spacers comprise a layered structure comprising pairs of alternating thin film materials with varying refractive index. In one or more embodiments, pair of films comprise silicon dioxide (SiO₂) and titanium dioxide (TiO₂) layers. In one or more embodiments, pair of films comprise silicon dioxide (SiO₂) and niobium pentoxide (NbO₅) layers.

Embodiments herein advantageously provide enhanced light output while maintaining electrical performance, and reliability. For example, flux gains have been demonstrated for devices with deeper junction spacers (e.g., SiO₂) in combination with higher proportions of doped n-layers. In addition, gains in wall-plug efficiency (WPE) and external quantum efficiency (EQE) (for example at 85° C.) are realized.

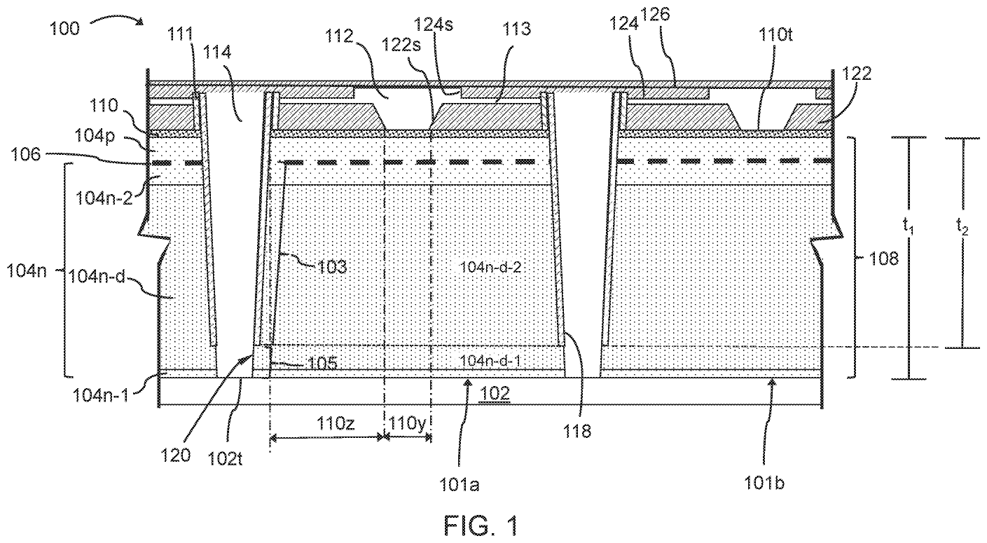

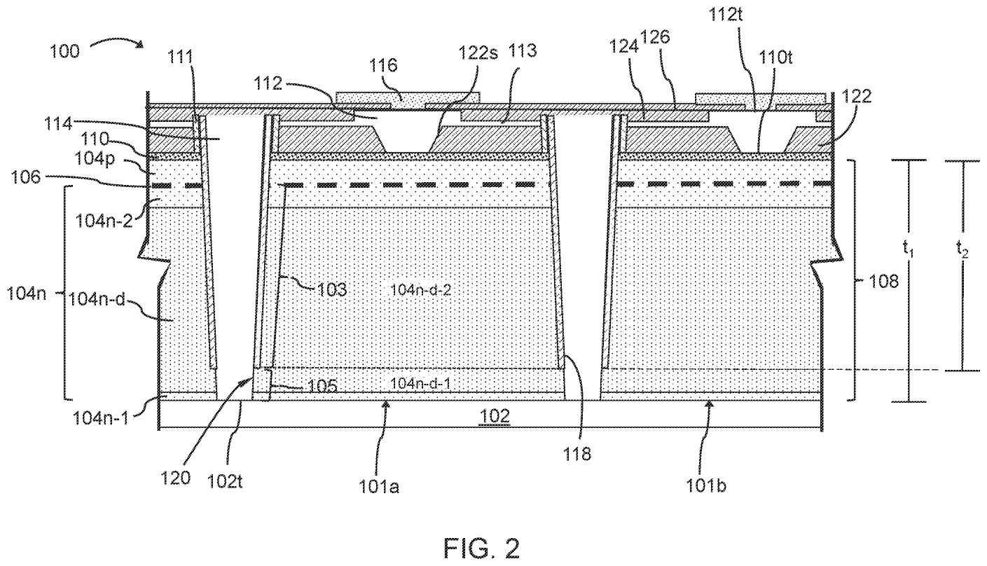

FIG. 1 is a cross-sectional view of a portion of a light emitting diode (LED) array according to one or more embodiments, and FIG. 2 is the cross-sectional view of a portion of a light emitting diode (LED) array according to one or more embodiments further including anode metallization bumps. A plurality of mesas 101a, 101b comprise semiconductor layers 108 having a total thickness t₁. The semiconductor layers 108 include: an n-type layer 104n, an active region 106and a p-type layer 104p. In one or more embodiments, the n-type layer comprises: a first n-type template layer 104n-1, a doped N-type layer 104n-d having a first portion 104n-d-1 and a second portion 104n-d-2, and a second n-type template layer 104n-2. In one or more embodiments, the doped N-type layer 104n-d constitutes greater than or equal to 20% of the thickness of the semiconductor layers, including greater than or equal to 20% to less than or equal to 95% of the thickness, and all values and subranges therebetween. In one or more embodiments, the doped N-type layer 104n-d comprises a doping level in a range of greater than or equal to 1E17 to less than or equal to 5E20 cm⁻³, including all values and subranges in between. In an embodiment, the doping level is greater than or equal to 1E18 to less than or equal to 5E19 cm⁻³.

In FIGS. 1-2, the n-type layer has an uninsulated portion of the n-type layer 103 and an insulated portion of the n-type layer 105. The uninsulated portion of the n-type layer 105 comprises: a doped N-type material, which in this embodiment is the first portion 104n-d-1of the doped N-type layer 104n-d and the first n-type template layer 104n-1. The insulated portion of the n-type layer 103 comprises: the second portion 104n-d-2 of the doped N-type layer 104n-d and the second n-type template layer 104n-2.

The semiconductor layers 108 are grown on a substrate 102. The semiconductor layers 108 are thereafter processed with other materials and etched and otherwise prepared to fabricate the LED arrays and/or devices. The substrate may be any substrate known to one of skill in the art. In one or more embodiments, the substrate comprises one or more of sapphire, silicon carbide, silicon (Si), quartz, magnesium oxide (MgO), zinc oxide (ZnO), spinel, and the like. In one or more embodiments, the substrate is not patterned prior to the growth of the epitaxial layer(s). Thus, in some embodiments, the substrate is not patterned and can be considered to be flat or substantially flat. In other embodiments, the substrate is patterned, e.g. patterned sapphire substrate (PSS). In one or more embodiments, the semiconductor layers 108 are grown on a growth substrate that comprises sapphire.

The n-type template layers 104n-1, 104n-2 according to one or more embodiments comprise epitaxial layers, III-nitride layers or epitaxial III-nitride layers, which are undoped or minimally doped or unintentionally doped or otherwise doped (e.g., to high concentration). Any doping present in the n-type template layers 104n-1, 104n-2 may be to a degree less than that of the doped N-type layer. In one or more embodiments, the n-type template layers 104n-1, 104n-2 may doped with one or more of silicon (Si), oxygen (O), boron (B), phosphorus (P), germanium (Ge), or manganese (Mn).

In one or more embodiments, the n-type template layers 104n-1, 104n-2 and the p-type layer 104p comprise a III-nitride material, and in specific embodiments epitaxial III-nitride material. In some embodiments, the III-nitride material comprises one or more of gallium (Ga), aluminum (Al), and indium (In). Thus, in some embodiments, the n-type template layers 104n-1, 104n-2 and the p-type layer 104p comprises one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like. In one or more embodiments, the n-type template layers 104n-1, 104n-2 and the p-type layer 104p comprise a III-nitride material, and in specific embodiments epitaxial III-nitride material. In some embodiments, the III-nitride material comprises one or more of gallium (Ga), aluminum (Al), and indium (In). Thus, in some embodiments, the n-type template layers 104n-1, 104n-2 and the p-type layer 104p comprises one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like.

In one or more embodiments, the substrate 102 is placed in a metalorganic vapor-phase epitaxy (MOVPE) reactor for epitaxy of LED device layers to grow the semiconductor layers 108.

In one or more embodiments, the semiconductor layers 108 comprise a stack of undoped III-nitride material and doped III-nitride material. The doped N-type layer 104n-d comprises doped III-nitride materials according to one or more embodiments. The doped N-type layer 104n-d may be the same material as the n-type template layer doped with, for example, silicon (Si).

In one or more embodiments, the semiconductor layers 108 have a combined thickness t₁ in a range of from about 1 μm to about 10 μm, including all values and subranges therebetween, including a range of from about 1 μm to about 9 μm, 1 μm to about 8 μm, 1 μm to about 7 μm, 1 μm to about 6 μm, 1 μm to about 5 μm, 1 μm to about 4 μm, 1 μm to about 3 μm, 3 μm to about 10 μm, 3 μm to about 9 μm, 3 μm to about 8 μm, 3 μm to about 7 μm, 3 μm to about 6 μm, 3 μm to about 5 μm, 3 μm to about 4 μm, 4 μm to about 10 μm, 4 μm to about 9 μm, 4 μm to about 8 μm, 4 μm to about 7 μm, 4 μm to about 6 μm, 4 μm to about 5 μm, 5 μm to about 10 μm, 5 μm to about 9 μm, 5 μm to about 8 μm, 5 μm to about 7 μm, 5 μm to about 6 μm, 6 μm to about 10 μm, 6 μm to about 9 μm, 6 μm to about 8 μm, 6 μm to about 7 μm, 7 μm to about 10 μm, 7 μm to about 9 μm, or 7 μm to about 8 μm.

In one or more embodiments, the active region 106 is formed between the second n-type template layer 104n-2 and the p-type layer 104p. The active region 106 may comprise any appropriate materials known to one of skill in the art. In one or more embodiments, the active region 106 is comprised of a III-nitride material multiple quantum wells (MQW), and a III-nitride electron blocking layer.

A current spreading layer 110 is deposited on the p-type layer 104p. In some embodiments, the current spreading layer 110 is deposited directly on the p-type layer 104p. In other embodiments, not illustrated, there may be one or more additional layer between the p-type layer 104p and the current spreading layer 110. The current spreading layer 110 may be deposited by any appropriate technique known to the skilled artisan. In one or more embodiments, the p-contact layer 110 is deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

In one or more embodiments, the current spreading layer comprises a transparent material. The current spreading layer is separate from a reflecting layer. In this way, the function of current spreading is achieved in a different layer from the function of reflection. In one or more embodiments, a current spreading layer comprises indium tin oxide (ITO) or other suitable conducting, transparent materials, e.g., transparent conductive oxides (TCO), such as indium zinc oxide (IZO). In one or more embodiments, the current spreading layer has a thickness in a range of from 5 nm to 100 nm.

During fabrication, a dielectric material is typically deposited on the current spreading layer 110. In some embodiments, the dielectric material is deposited directly on the current spreading layer 110. In other embodiments, there may be one or more additional layers between the dielectric material and the current spreading layer 110. The dielectric material may be deposited by any appropriate technique known to the skilled artisan. In one or more embodiments, the dielectric material is deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD). The dielectric material upon etching and/or further processing becomes the mesa dielectric layer 122 of the final device.

In one or more embodiments, the mesa dielectric layer 122 is directly on the current spreading layer 110. In one or more embodiments, the current spreading layer 110 has a first portion 110y and a second portion 110z. The first portion 110y and the second portion 110z are lateral portions of the current spreading layer 110. In one or more embodiments, the mesa dielectric layer 122 is separated by a via opening defined by mesa dielectric sidewall 122s and an exposed surface of the current spreading layer 110t.

“Sputter deposition” as used herein refers to a physical vapor deposition (PVD) method of thin film deposition by sputtering. In sputter deposition, a material, e.g. a metal, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e. two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition (CVD)” refers to a process in which films of materials are deposited from the vapor phase by decomposition of chemicals on a substrate surface. In CVD, a substrate surface is exposed to precursors and/or co-reagents simultaneous or substantially simultaneously. As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. A PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g. a thin film on a substrate. Similarly to a thermal ALD process, a purge step maybe conducted between the delivery of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

The dielectric material is etched and/or patterned, onto which one or more p-contact materials 112 are deposited on the mesa dielectric layer 122 and in the via opening defined by mesa dielectric sidewall 122s. Exemplary p-contact materials include but are not limited to: a p-contact layer, a guard layer, and/or a p-metal material.

In one or more embodiments, a p-contact layer 113 (part of the p-contact materials 112) is directly on a top surface of the mesa dielectric layer 122, on the mesa dielectric sidewall 122s, and on the exposed surface 110t of the first portion 110y of the current spreading layer 110. In one or more embodiments, the p-contact layer 113 is substantially conformal to via opening defined by mesa dielectric sidewall 122s. As used herein, a layer which is “substantially conformal” refers to a layer where the thickness is about the same throughout. A layer which is substantially conformal varies in thickness by less than or equal to about 5%, 2%, 1% or 0.5%. In one or more embodiments, a guard layer (part of p-contact materials 112 and not separately numbered) is on the p-contact layer above both the first portion 110y and second portions 110z of the current spreading layer 110. Without intending to be bound by theory, according to one or more embodiments, the guard layer may prevent metal ions from the p-contact layer 113 from migrating and shorting the device.

During fabrication, a hard mask material (not numbered) is typically deposited on the p-contact layer 113. In some embodiments, the hard mask material is deposited directly on the p-contact layer 113. In other embodiments, there may be one or more additional layers between the hard mask material and the p-contact layer 113. The hard mask material may be deposited by any appropriate technique known to the skilled artisan. In one or more embodiments, the hard mask material is deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD). The hard mask material upon etching and/or further processing becomes the hard mask layer 124 of the final device.

In one or more embodiments, the hard mask layer may be fabricated using materials and patterning techniques which are known in the art. In some embodiments, the hard mask layer comprises a dielectric material. Suitable dielectric materials include, but are not limited to, silicon oxide (SiO), silicon nitride (Si₃N₄), silicon carbide (SiC), aluminum oxide (AlOₓ), aluminum nitride (AlN) and combinations thereof. The skilled artisan will recognize that the use of formulas like SiO, to represent silicon oxide, does not imply any particular stoichiometric relationship between the elements. The formula merely identifies the primary elements of the film.

In one or more embodiments, the p-contact layer 113 may comprise any suitable metal known to one of skill in the art. In one or more embodiments, the p-contact layer 113 is a reflective layer. In one or more embodiments, the p-contact layer 113 comprises one or more of nickel (Ni) and silver (Ag).

In one or more embodiments, the hard mask material is subject to a first process including etching, and conformal deposition of dielectric material for inner spacers 111. The inner spacers may comprise any dielectric material suitable for the application.

In one or more embodiments, the hard mask material, the p-contact layer 113, and a portion of the semiconductor layers 108 (from the p-type layer 104p along a portion of the doped N-type layer 104n-d) are subject to a second process, for further patterning and/or etching to form openings. In one or more embodiments, the patterning is according to any appropriate technique known to one of skill in the art. In one or more embodiments, the patterned is conducted by etching. According to one or more embodiments, conventional masking, wet etching and/or dry etching processes can be used to for patterning.

According to one or more embodiments, a dielectric material is deposited conformally in the openings on exposed surfaces of the p-type layer 104p, the second n-type template layer 104n-2, the active region 106, the second portion of the doped N-type layer 104n-d-2, the p-contact layer 110, and the hard mask layer to form junction spacers 118 that contact the p-contact layer 110, the hard mask layer, the p-type layer 104p, the active region 106, the second n-type template layer 104n-2, and the second portion of the doped N-type layer 104n-d-2. In one or more embodiments, the junction spacers 118 span a longitudinal distance t₂ of greater than or equal to 20% of the thickness of the semiconductor layers t₁, including greater than or equal to 20% of t₁ and less than 95% of t₁, including all values and subranges therebetween.

As used herein, the term “dielectric” refers to an electrical insulator material that can be polarized by an applied electric field. In one or more embodiments, the junction spacers 118 comprise a material whose refractive index is lower than a refractive index of the semiconductor layers. In one or more embodiments, the junction spacers 118 provide a total internal reflection (TIR) to increase side-wall reflectivity. In one or more embodiments, the junction spacers 118 comprise both a material whose refractive index is lower than a refractive index of the semiconductor layers, and provides a total internal reflection (TIR). In one or more embodiments, the junction spacers 118 include, but are not limited to, oxides, e.g., silicon oxide (SiO₂), aluminum oxide (Al₂O₃), silicon oxynitride (Si₂ON₂), nitrides, e.g., silicon nitride (Si₃N₄). In one or more embodiments, the junction spacers 118 comprise silicon nitride (Si₃N₄). In other embodiments, the junction spacers 118 comprise silicon oxide (SiO₂). In some embodiments, the junction spacers 118 composition is non-stoichiometrie relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g. silicon oxycarbide (SiOC)), and oxynitrocarbides (e.g. silicon oxycarbonitride (SiNCO)). In one or more embodiments, the dielectric material of the junction spacers comprise a material comprising an oxide, a nitride, an oxycarbide, or an oxynitrocarbide of silicon or aluminum and/or combinations thereof. In one or more embodiments, the dielectric material of the junction spacers comprise a material selected from the group consisting of silicon dioxide (SiO₂), aluminum oxide (Al₂O₃), silicon oxynitride (Si₂ON₂), and silicon nitride (Si₃N₄), and/or combinations thereof.

In some embodiments, the junction spacers 118 may be a distributed Bragg reflector (DBR). As used herein, a “distributed Bragg reflector” (DBR) refers to a structure (e.g. a mirror) formed from a multilayer stack of alternating thin film materials with varying refractive index, for example high-index and low-index films. In one or more embodiments, pair of films comprise silicon dioxide (SiO₂) and titanium dioxide (TiO₂) layers. In one or more embodiments, pair of films comprise silicon dioxide (SiO₂) and niobium pentoxide (NbO₅) layers.

In one or more embodiments, the junction spacers 118 are deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

In one or more embodiments, the junction spacers 118 have a thickness in a range of from about 200 nm to about 1 μm, for example, about 300 nm to about 1 μm, about 400 nm to about 1 μm, about 500 nm to about 1 μm, about 600 nm to about 1 μm, about 700 nm to about 1 μm, about 800 nm to about 1 μm, about 500 nm to about 1 μm, about 200 nm to about 900 nm, 300 nm to about 900 nm, about 400 nm to about 900 nm, about 500 nm to about 900 nm, about 600 nm to about 900 nm, about 700 nm to about 900 nm, about 800 nm to about 900 nm, about 200 nm to about 800 nm, 300 nm to about 800 nm, about 400 nm to about 800 nm, about 500 nm to about 800 nm, about 600 nm to about 800 nm, about 700 nm to about 800 nm, about 200 nm to about 700 nm, about 300 nm to about 700 nm, about 400 nm to about 700 nm, about 500 nm to about 700 nm, about 600 nm to about 700 nm, about 200 nm to about 600 nm, about 300 nm to about 600 nm, about 400 nm to about 600 nm, about 500 nm to about 600 nm, about 200 nm to about 500 nm, about 300 nm to about 500 nm, about 300 nm to about 400 nm, about 200 nm to about 400 nm, or about 300 nm to about 400 nm.

After the dielectric material is conformally deposited, the substrate is etched, thereby removing any residual dielectric material on a bottom surface of the opening along with etching the first portion of the doped N-type layer 104n-d-1 and the first n-type template layer 104n-1 to expose sidewalls of the first portion of the doped N-type layer 104n-d-1 and the first n-type template layer 104n-1 and to expose a top surface 102t of the substrate 102 to form trenches (by increasing the depth of the openings). A surface 120 of the exposed sidewall of the first portion of the doped N-type layer 104n-d-1 facilitates ohmic contact formation with a cathode comprising the n-contact material 114. In one or more embodiments, the surface 120 of the first portion of the doped N-type layer 104n-d-1 is effective to provide an active metal-semiconductor contact.

Also, in so etching, a plurality of mesas 101a, 101b are prepared, defining pixels having sidewalls, and each of the mesas comprising the semiconductor layers 108 having the thickness t₁. In one or more embodiments, the etching is selective such that the junction spacers 118 remain on the sidewalls of the mesas 101a, 101b.

The substrate is further patterned in that the hard mask layer is further etched to expose the p-contact layer 113 to form anode sidewalls 124s in the hard mask layer 124s, which with the top surface of the p-contact layer 113 define hard mask openings. In one or more embodiments, the substrate is be patterned according to any appropriate technique known one of skill in the art, such as a masking and etching process used in semiconductor processing.

Thereafter, a metal, e.g., an electrode metal is deposited on the substrate, which fills the trenches and hard mask openings. The electrode metal, can comprise any appropriate material known to the skilled artisan. In one or more embodiments, the electrode metal comprises copper and the electrode metal material is deposited by electrochemical deposition (ECD) of the copper.

The substrate is thereafter processed to remove excess electrode metal. In one or more embodiments, the processing includes planarizing, etching, and/or polishing. As used herein, the term “planarizing” refers to a process of smoothing surfaces and includes, but is not limited to, chemical mechanical polishing/planarization (CMP), etching, and the like. Remaining electrode metal yields the cathode comprising the n-contact material 114 and a p-material (part of p-contact materials 112). The n-contact material 114 provides optical isolation between each of the mesas, and electrically contacts the first portion of the doped N-type layer and the first n-type template layer of each of the mesas along the sidewalls. In one or more embodiments, the cathodes span a longitudinal distance that is at least the same as the thickness t₁ of the semiconductor layers 108.

In one or more embodiments, an anode contacting each mesa comprises the one or more p-contact materials 112. Each current spreading layer 110 being in contact with each of the p-contact materials 112 at its first portion 110y and the p-type layers 104p of the mesas 101a, 101b. In one or more embodiments, each of the anodes comprises one or more via openings defined by the anode sidewalls 124s.

In one or more embodiments, a passivation material is thereafter deposited on the substrate. In some embodiments, the passivation material is deposited directly on the planarized n-contact material 114, the planarized p-contact material 112, and the remaining hard mask layer 124. In some embodiments, there may be one or more additional layers deposited on the substrate before and/or after the passivation material is deposited. In some embodiments, the passivation material comprises the same material as the hard mask layer. The passivation material upon etching and/or any further processing becomes part of the passivation layer 126 of the final device.

In one or more embodiments, the passivation material may be deposited by any suitable technique known to one of skill in the art. In one or more embodiments, the passivation layer is deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

In one or more embodiments, the passivation layer comprise by any suitable material known to one of skill in the art. In one or more embodiments, the passivation layer comprises a dielectric material. Suitable dielectric materials include, but are not limited to, silicon oxide (SiO), silicon nitride (Si₃N₄), silicon carbide (SiC), aluminum oxide (AlOₓ), aluminum nitride (AlN) and combinations thereof.

Turning to FIG. 2, in one or more embodiments, the passivation layer is patterned to form at least one opening, exposing a top surface 112t of the p-contact materials. The passivation layer may be patterned using any suitable technique known to one of skill in the art including, but not limited to, lithography, wet etching, or dry etching.

Under bump metallization (UBM) material forms under bump metallization (UBM) layers. In one or more embodiments, the UBM layer is an anode metallization bump 116, which is deposited in the passivation layer openings and/or over the passivation layer and is in contact with the anode, namely the p-contact materials 112. As used herein, “under bump metallization (UBM)” refers to the metal layer which is utilized for connecting a die to a substrate with solder bumps for flip-chip packages. In one or more embodiments, the UBM layer 116 may be a patterned, thin-film stack of material that provides an electrical connection from the die to a solder bump, provides a barrier function to limit unwanted diffusion from the bump to the die, and provides a mechanical interconnection of the solder bump to the die through adhesion to the die passivation and attachment to a solder bump pad. The anode metallization bump 116 may comprise any suitable metal known to the skilled artisan. In one or more embodiments, the anode metallization bump 116 comprises gold (Au).

In one or more embodiments, under bump metallization (UBM) may be achieved by any technique known to one of skill in the art including, but not limited to, a dry vacuum sputter method combined with electroplating. In one or more embodiments, a dry vacuum sputter method combined with electroplating consists of multi-metal layers being sputtered in a high temperature evaporation system.

The devices of FIGS. 1-2 may be used in end devices such as displays, or further processed.

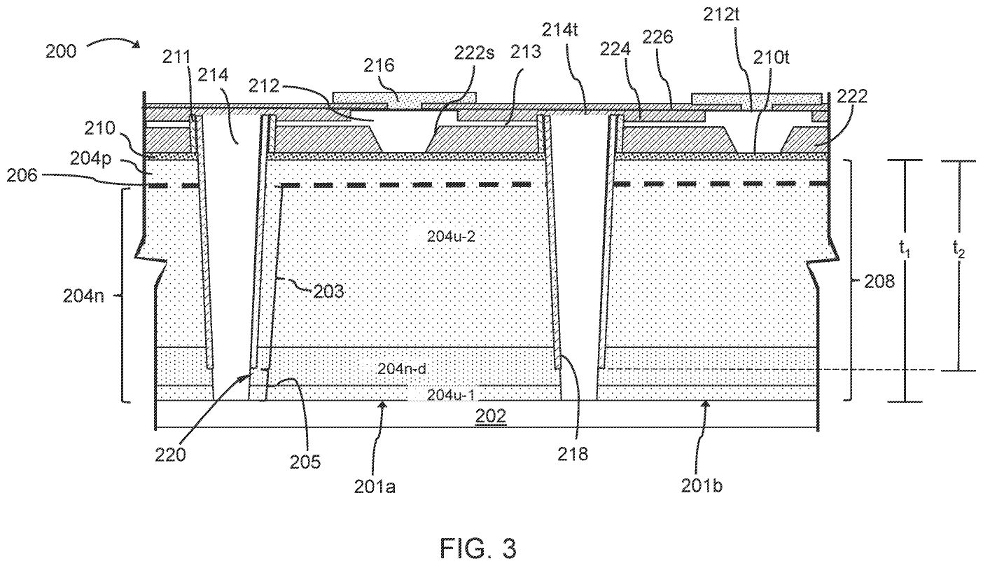

FIG. 3 is a cross-sectional view of a portion of a light emitting diode (LED) array according to one or more embodiments. The device of FIG. 3 is fabricated in accordance with the materials and methods analogously associated with FIGS. 1-2. FIG. 3 provides a version of the n-type layer 204n in more general terms as compared to the n-type layer 104n of FIGS. 1-2. A plurality of active metal-semiconductor contacts 220 electrically contact n-contact material 214 and comprise an uninsulated portion 205 of an n-type layer 204n of each mesa 201a, 201b, and the like along sidewalls of the mesas. The uninsulated portion 205 of the n-type layer 204n comprises a doped N-type material 204n-d, which in one or more embodiments, is a doped N-type layer. The active metal-semiconductor contacts 220 are the exposed surfaces of the doped N-type material 204n-d. In this embodiment, the doped N-type material 204n-d is also part of an insulated portion 203 of the n-type layer 204n. The doped N-type material 204n-d may constitute greater than or equal to 20% of the thickness of the semiconductor layers.

Each mesa 201a, 201b defines a pixel having sidewalls made of semiconductor layers 208 having a total thickness t₁, the semiconductor layers 208 including the n-type layer 204n, an active region 206, and a p-type layer 204p. In one or more embodiments, the semiconductor layers 208 are grown on a substrate 202. In one or more embodiments, the total thickness t₁ is in a range of from 1 μm to 10 μm, including all values and subranges therebetween. In one or more embodiments, a combined thickness of the p-type layer 204p and the active region 206 is 30% of the thickness (e.g., 0.3 μm to 3 μm), and the a n-type layer 204n is 70% (e.g., 0.7 μm to 7 μm).

A current spreading layer 210 is disposed on the p-type layer 204p of each mesa 201a, 201b. A junction spacer 218 is conformal to a portion of the sidewalls, insulating the current spreading layer 210, the p-type layer 204b, the active region 206, and an insulated portion of the n-type layer 203 of each mesa from an n-contact material 214. A cathode comprising the n-contact material is between each of the mesas201a, 201b, providing optical isolation therebetween. An anode comprising one or more p-contact materials 212 is in contact with the current spreading layer 210.

In one or more embodiments, the n-type layer 204n comprises: the doped N-type material 204n-d, and one or more regions of undoped or lesser-doped n-type material 204u-1, 204u-2 wherein any doping content of the undoped or lesser-doped n-type material 204u-1, 204u-2is less than a doping content of the doped N-type material 204n-d, and a first portion of the region of doped N-type material 204n-d is located in the uninsulated portion 205 of the n-type layer 204n and a second portion of the region of doped N-type material 204n-d is located in the insulated portion 203 of the n-type layer 204n.

Inner spacer 211 of dielectric material contacts a dielectric layer 222, the p-contact layer 213, the current spreading layer 210, and junction spacer 218 of dielectric material. In one or more embodiments, the junction spacers span a longitudinal distance of greater than or equal to 20% of the thickness of the semiconductor layers. One or more p-contact materials 212 are deposited on a mesa dielectric layer 122 and in a via opening defined by mesa dielectric sidewall 122s. Exemplary p-contact materials include but are not limited to: a p-contact layer 213, a guard layer, and/or a p-metal material.

Analogous to FIG. 2, in one or more embodiments, the passivation layer 226 is patterned to form at least one opening, exposing a top surface 212t of the p-contact materials 212 and a top surface 214t of the n-contact material 214. The passivation layer 226 may be patterned using any suitable technique known to one of skill in the art including, but not limited to, lithography, wet etching, or dry etching. In one or more embodiments, one or more UBM layers comprise an anode metallization bump 216, which are deposited in passivation layer openings and/or over the passivation layer and is in contact with the anode, namely the p-contact materials 212.

The device of FIG. 3 may be used in end devices such as displays, or further processed.

Further processing of array according to embodiments herein including FIGS. 1-3 include deposition of a down-converter material, e.g. layers of a phosphor material. In some embodiments, LED arrays herein are further processed to include optical elements such as lenses, metalenses, and/or pre-collimators. Optical elements can also or alternatively include apertures, filters, a Fresnel lens, a convex lens, a concave lens, or any other suitable optical element that affects the projected light from the light emitting array. Additionally, one or more of the optical elements can have one or more coatings, including UV blocking or anti-reflective coatings. In some embodiments, optics can be used to correct or minimize two- or three-dimensional optical errors including pincushion distortion, barrel distortion, longitudinal chromatic aberration, spherical aberration, chromatic aberration, field curvature, astigmatism, or any other type of optical error. In some embodiments, optical elements can be used to magnify and/or correct images. Advantageously, in some embodiments magnification of display images allows the light emitting array to be physically smaller, of less weight, and require less power than larger displays. Additionally, magnification can increase a field of view of the displayed content allowing display presentation equals a user's normal field of view.

### Applications

LED devices disclosed herein may be monolithic arrays or matrixes. An LED device may be affixed to a backplane for use in a final application. Illumination arrays and lens systems may incorporate LED devices disclosed herein. Applications include but are not limited to beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. Light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, automotive headlights, architectural and area illumination, and street lighting. Other applications include display devices.

### Display Devices

Some display devices comprise arrays and groups of LEDs or pixels, which include the embodiments disclosed herein.

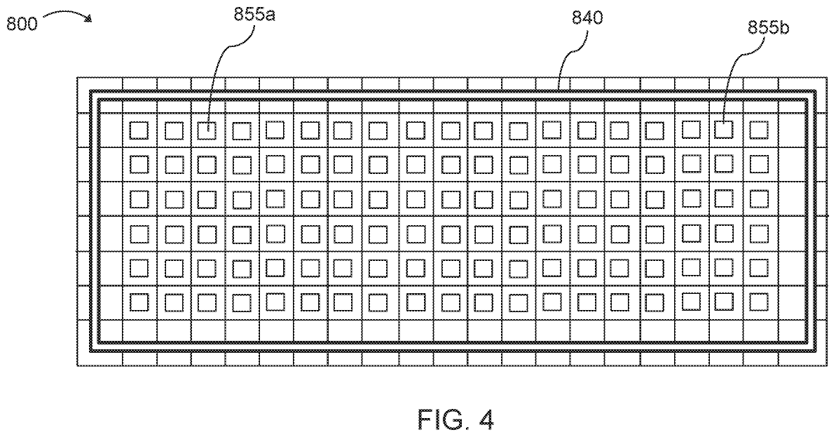

FIG. 4 shows a top plan view of an LED monolithic array 800 comprising a plurality of pixels arranged in a grid of 6×19. Pixels 855a and 855b are examples. In this embodiment, a common cathode 840 is connected to the pixels. Anodes, not shown, present on the underside are included with each pixel. In one or more embodiments, the array comprises an arrangement of 2×2 mesas, 4×4 mesas, 20×20 mesas, 50×50 mesas, 100×100 mesas, or n1×n2 mesas, where each of n1 and n2 is a number in a range of from 2 to 1000, and n1 and n2 can be equal or not equal.

In one or more embodiments, arrays of LEDs (traditional, mini-LEDs, or uLEDs) are used. In one or more embodiments, micro-LEDs can support high density pixels having a lateral dimension less than 100 μm by 100 μm. In some embodiments, micro-LEDs with dimensions of about 50 μm in diameter or width and smaller can be used. Such micro-LEDs can be used for the manufacture of color displays by aligning in close proximity micro-LEDs comprising red, blue and green wavelengths. Such micro-LEDs can be used for the manufacture of monochrome displays, such as those for automotive lighting arrangements.

In some embodiments, the light emitting arrays include small numbers of LEDs positioned on substrates that are centimeter scale area or greater. In some embodiments, the light emitting arrays include micro-LED pixel arrays with hundreds, thousands, or millions of light emitting LEDs positioned together on centimeter scale area substrates or smaller. In some embodiments, LEDs can include light emitting diodes sized between 1 microns and 500 microns. The light emitting array(s) can be monochromatic, RGB, or other desired chromaticity. In some embodiments, pixels can be square, rectangular, hexagonal, or have curved perimeter. Pixels can be of the same size, of differing sizes, or similarly sized and grouped to present larger effective pixel size.

In some embodiments, light emitting pixels and circuitry supporting light emitting arrays are packaged and optionally include a submount or printed circuit board connected for powering and controlling light production by semiconductor LEDs. In certain embodiments, a printed circuit board supporting light emitting array includes electrical vias, heat sinks, ground planes, electrical traces, and flip chip or other mounting systems. The submount or printed circuit board may be formed of any suitable material, such as ceramic, silicon, aluminum, etc. If the submount material is conductive, an insulating layer is formed over the substrate material, and the metal electrode pattern is formed over the insulating layer. The submount can act as a mechanical support, providing an electrical interface between electrodes on the light emitting array and a power supply, and also provide heat sink functionality.

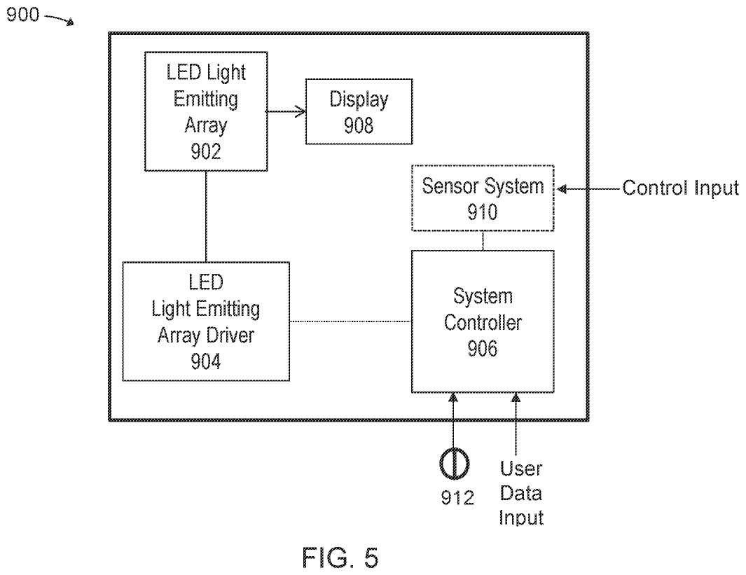

FIG. 5 schematically illustrates an exemplary display system 900 utilizing LEDs disclosed herein. The display system 900 comprises an LED light emitting array 902 and display 908 in electrical communication with an LED driver 904. The display system 900 also comprises a system controller 906, such as a microprocessor. The controller 906 is coupled to the LED driver 904. The controller 906 may also be coupled to the display 908 and to optional sensor(s) 910, and be powered by power source 912. In one or more embodiments, user data input is provided to system controller 906.

Optionally sensors 910 with control input may include, for example, positional sensors (e.g., a gyroscope and/or accelerometer) and/or other sensors that may be used to determine the position, speed, and orientation of system. The signals from the sensors 910 may be supplied to the controller 906 to be used to determine the appropriate course of action of the controller 906 (e.g., which LEDs are currently illuminating a target and which LEDs will be illuminating the target a predetermined amount of time later).

In operation, illumination from some or all of the pixels of the LED array in 902 may be adjusted-deactivated, operated at full intensity, or operated at an intermediate intensity. As noted above, beam focus or steering of light emitted by the LED array in 902 can be performed electronically by activating one or more subsets of the pixels, to permit dynamic adjustment of the beam shape without moving optics or changing the focus of the lens in the lighting apparatus.

Other applications of LED arrays and devices herein include visualization systems, such as virtual reality systems and augmented reality systems and an augmented reality/virtual reality (AR/VR) systems, which may utilize any of the LEDs, including uLEDs disclosed herein. One or more AR/VR systems include: augmented (AR) or virtual reality (VR) headsets, glasses, or projectors. Such AR/VR systems includes an LED light emitting array, an LED driver (or light emitting array controller), a system controller, an AR or VR display, a sensor system. Control input may be provided to the sensor system, while power and user data input is provided to the system controller. As will be understood, in some embodiments modules included in the AR/VR system can be compactly arranged in a single structure, or one or more elements can be separately mounted and connected via wireless or wired communication. For example, the light emitting array, AR or VR display, and sensor system can be mounted on a headset or glasses, with the LED driver and/or system controller separately mounted.

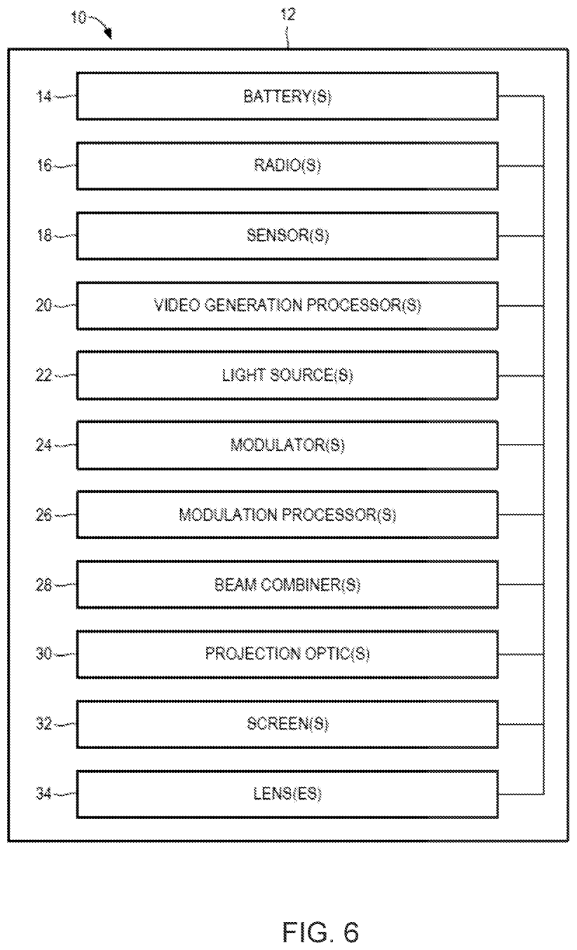

FIG. 6 shows a block diagram of an example of a visualization system 10. The visualization system 10 can include a wearable housing 12, such as a headset or goggles. The bousing 12 can mechanically support and house the elements detailed below. In some examples, one or more of the elements detailed below can be included in one or more additional housings that can be separate from the wearable housing 12 and couplable to the wearable housing 12 wirelessly and/or via a wired connection. For example, a separate housing can reduce the weight of wearable goggles, such as by including batteries, radios, and other elements. The housing 12 can include one or more batteries 14, which can electrically power any or all of the elements detailed below. The housing 12 can include circuitry that can electrically couple to an external power supply, such as a wall outlet, to recharge the batteries 14. The housing 12 can include one or more radios 16 to communicate wirelessly with a server or network via a suitable protocol, such as WiFi.

The visualization system 10 can include one or more sensors 18, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 18 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 18 can capture a real-time video image of the surroundings proximate a user.

The visualization system 10 can include one or more video generation processors 20. The one or more video generation processors 20 can receive, from a server and/or a storage medium, scene data that represents a three-dimensional scene, such as a set of position coordinates for objects in the scene or a depth map of the scene. The one or more video generation processors 20 can receive one or more sensor signals from the one or more sensors 18. In response to the scene data, which represents the surroundings, and at least one sensor signal, which represents the location and/or orientation of the user with respect to the surroundings, the one or more video generation processors 20 can generate at least one video signal that corresponds to a view of the scene. In some examples, the one or more video generation processors 20 can generate two video signals, one for each eye of the user, that represent a view of the scene from a point of view of the left eye and the right eye of the user, respectively. In some examples, the one or more video generation processors 20 can generate more than two video signals and combine the video signals to provide one video signal for both eyes, two video signals for the two eyes, or other combinations.

The visualization system 10 can include one or more light sources 22 that can provide light for a display of the visualization system 10. Suitable light sources 22 can include a light-emitting diode, a monolithic light-emitting diode, a plurality of light-emitting diodes, an array of light-emitting diodes, an array of light-emitting diodes disposed on a common substrate, a segmented light-emitting diode that is disposed on a single substrate and has light-emitting diode elements that are individually addressable and controllable (and/or controllable in groups and/or subsets), an array of micro-light-emitting diodes (microLEDs), and others.

A light-emitting diode can be white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, that has a wavelength greater than a wavelength of the excitation light.

The one or more light sources 22 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The visualization system 10 can include one or more modulators 24. The modulators 24 can be implemented in one of at least two configurations.

In a first configuration, the modulators 24 can include circuitry that can modulate the light sources 22 directly. For example, the light sources 22 can include an array of light-emitting diodes, and the modulators 24 can directly modulate the electrical power, electrical voltage, and/or electrical current directed to each light-emitting diode in the array to form modulated light. The modulation can be performed in an analog manner and/or a digital manner. In some examples, the light sources 22 can include an array of red light-emitting diodes, an array of green light-emitting diodes, and an array of blue light-emitting diodes, and the modulators 24 can directly modulate the red light-emitting diodes, the green light-emitting diodes, and the blue light-emitting diodes to form the modulated light to produce a specified image.

In a second configuration, the modulators 24 can include a modulation panel, such as a liquid crystal panel. The light sources 22 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 24 can include multiple modulation panels that can modulate different colors of light. For example, the modulators 24 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 24 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 10 can include one or more modulation processors 26, which can receive a video signal, such as from the one or more video generation processors 20, and, in response, can produce an electrical modulation signal. For configurations in which the modulators 24 directly modulate the light sources 22, the electrical modulation signal can drive the light sources 24. For configurations in which the modulators 24 include a modulation panel, the electrical modulation signal can drive the modulation panel.

The visualization system 10 can include one or more beam combiners 28 (also known as beam splitters 28), which can combine light beams of different colors to form a single multi-color beam. For configurations in which the light sources 22 can include multiple light-emitting diodes of different colors, the visualization system 10 can include one or more wavelength-sensitive (e.g., dichroic) beam splitters 28 that can combine the light of different colors to form a single multi-color beam.

The visualization system 10 can direct the modulated light toward the eyes of the viewer in one of at least two configurations. In a first configuration, the visualization system 10 can function as a projector, and can include suitable projection optics 30 that can project the modulated light onto one or more screens 32. The screens 32 can be located a suitable distance from an eye of the user. The visualization system 10 can optionally include one or more lenses 34 that can locate a virtual image of a screen 32 at a suitable distance from the eye, such as a close-focus distance, such as 500 mm, 750 mm, or another suitable distance. In some examples, the visualization system 10 can include a single screen 32, such that the modulated light can be directed toward both eyes of the user. In some examples, the visualization system 10 can include two screens 32, such that the modulated light from each screen 32 can be directed toward a respective eye of the user. In some examples, the visualization system 10 can include more than two screens 32. In a second configuration, the visualization system 10 can direct the modulated light directly into one or both eyes of a viewer. For example, the projection optics 30 can form an image on a retina of an eye of the user, or an image on each retina of the two eyes of the user.

For some configurations of augmented reality systems, the visualization system 10 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as If it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

### Embodiments

Various embodiments are listed below. It will be understood that the embodiments listed below may be combined with all aspects and other embodiments in accordance with the scope of the invention.

Embodiment (a). A light emitting diode (LED) array comprising: a plurality of mesas defining pixels having sidewalls, each of the mesas comprising semiconductor layers having a total thickness, the semiconductor layers including an n-type layer, an active region, and a p-type layer; a plurality of current spreading layers, each disposed on the p-type layer of each mesa; a plurality of junction spacers comprising a dielectric material conformal to a portion of the sidewalls, and insulating the current spreading layer, the p-type layer, the active region, and an insulated portion of the n-type layer of each mesa from an n-contact material; a plurality of active metal-semiconductor contacts electrically contacting the n-contact material and comprising an uninsulated portion of the n-type layer of each of the mesas along the sidewalls, the uninsulated portion of the n-type layer comprising a doped N-type material; a plurality of cathodes comprising the n-contact material between each of the mesas, providing optical isolation therebetween; and a plurality of anodes, each anode comprising one or more p-contact materials in contact with the current spreading layer.

Embodiment (b). The LED array of embodiment (a), wherein the junction spacers span a longitudinal distance of greater than or equal to 20% of the thickness of the semiconductor layers.

Embodiment (c). The LED array of embodiment (a) or (b), wherein the n-type layer comprises: the doped N-type material, and one or more regions of undoped or lesser-doped n-type material, wherein any doping content of the undoped or lesser-doped n-type material is less than a doping content of the doped N-type material and a first portion of the region of doped N-type material is located in the uninsulated portion of the n-type layer and a second portion of the region of doped n-type material is located in the insulated portion of the n-type layer.

Embodiment (d). The LED array of embodiment (c), wherein the doped N-type material is sandwiched between first and second regions of undoped or lesser-doped n-type material.

Embodiment (e). The LED array of any one of embodiments (a) to (d), wherein the doped N-type material constitutes greater than or equal to 20% of the thickness of the semiconductor layers.

Embodiment (f). The LED array any one of embodiments (a) to (e), wherein the thickness of the semiconductor layers t₁ is in a range of from 1 μm to 10 μm.

Embodiment (g). The LED array of any one of embodiments (a) to (f), wherein the dielectric material of the junction spacers comprises a material selected from the group consisting of silicon dioxide (SiO₂), aluminum oxide (AlOₓ), silicon oxynitride (Si₂ON₂), and silicon nitride (Si₃N₄), and/or combinations thereof.

Embodiment (b). The LED array of any one of embodiments (a) to (f), wherein the junction spacers comprise a layered structure effective as a distributed Bragg reflector (DBR).

Embodiment (i). The LED array of embodiment (h), wherein the junction spacers comprise a layered structure comprising one or more pairs of silicon dioxide (SiO₂) and titanium dioxide (TiO₂) layers or of silicon dioxide (SiO₂) and niobium pentoxide (NbO₅) layers.

Embodiment (j). The LED array of any one of embodiments (a) to (i), wherein the junction spacers have a thickness in a range of from 500 nm to 1 μm.

Embodiment (k). A display comprising: the light emitting diode (LED) array according to embodiment 1 affixed to a device substrate by anode metallization bumps.

Embodiment (l). The display of embodiment (k) further comprising a sapphire substrate on which the semiconductor layers were grown.

Embodiment (m). The display of embodiment (k) or (l), wherein the pixels emit a single color.

Embodiment (n). The display of any one of embodiments (k) to (l), wherein a first plurality of pixels is designed to emit a red color, a second plurality of pixels is designed to emit a blue color, and a third plurality of pixels is designed to emit a green color.

Embodiment (o). The display of any one of embodiments (k) to (n) comprising: light emitting diodes (LEDs) having at least one characteristic dimension of less than or equal to 500 micrometers, the character dimension being selected from the group consisting of: height, width, depth, thickness, and combinations thereof.

Embodiment (p). A method of manufacturing a light emitting diode (LED) device, the method comprising: growing a plurality of semiconductor layers including an n-type layer, an active region, and a p-type layer on a substrate; depositing a current spreading layer on the p-type layer; depositing a mesa dielectric material on the current spreading layer; etching the mesa dielectric material and forming inner spacers and deposing a p-contact layer; etching the current spreading layer, the p-type layer, the active region, and a portion of the n-type layer, to form openings; depositing a dielectric material conformally in the openings on exposed surfaces of the p-type layer, the active region, the portion of the n-type layer, the current spreading layer to form junction spacers that contact the current spreading layer, the inner spacers, the p-type layer, the active region, the portion of the n-type layer; etching a remaining portion of the n-type layer to expose a top surface of the substrate to form trenches and to expose a doped N-type material, and thereby preparing a plurality of mesas defining pixels having sidewalls, and each of the mesas comprising the semiconductor layers having a thickness; deposition of a hard mask material and forming anode sidewalls in the hard mask material, which with the top surface of the p-contact layer define hard mask openings; depositing an electrode metal on the substrate filling the trenches and the hard mask openings; and processing the substrate to remove excess electrode metal and to form an n-contact material providing optical isolation between each of the mesas, and electrically contacting the first portion of the doped N-type layer and the first n-type template layer of each of the mesas along the sidewalls, and to form a p-metal material in the hard mask openings.

Embodiment (q). The method of embodiment (p), wherein the semiconductor layers are grown on a substrate comprising sapphire, silicon carbide (SiC), silicon (Si), gallium arsenide (GaAs), or indium phosphide (InP).

Embodiment (r). The method of embodiment (p) or (q) further comprising depositing a passivation layer on the substrate, forming openings therein, and depositing anode metallization bumps over the passivation layer and in the openings of the passivation layer.

Embodiment(s). The method of any one of embodiments (p) to (r), wherein the junction spacers span a longitudinal distance of greater than or equal to 20% of the thickness of the semiconductor layers.

Embodiment (t). The method of any one of embodiments (p) to(s), wherein the dielectric material of the junction spacers comprises a material selected from the group consisting of silicon dioxide (SiO₂), aluminum oxide (Al₂O₃), silicon oxynitride (Si₂ON₂), and silicon nitride (Si₃N₄), and/or combinations thereof.

Embodiment (u). The method of any one of embodiments (p) to(s), wherein the dielectric material of the junction spacers comprises a layered structure effective as a distributed Bragg reflector (DBR).

Embodiment (v). The method of any one of embodiment (u), wherein the junction spacers comprise a layered structure comprising one or more pairs of silicon dioxide (SiO₂) and titanium dioxide (TiO₂) layers or of silicon dioxide (SiO₂) and niobium pentoxide (NbO₅) layers.

Reference throughout this specification to “one embodiment” “certain embodiments” “one or more embodiment” or “an embodiment” means that a particular feature, structure, material, or characteristic described in connection with the embodiment is included in at least one embodiment of the disclosure. Thus, the appearances of the phrases such as “in one or more embodiments” “in certain embodiments” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A light emitting diode (LED) array comprising:
a plurality of mesas defining pixels having sidewalls, each of the mesas comprising semiconductor layers having a total thickness, the semiconductor layers including an n-type layer, an active region, and a p-type layer;
a plurality of current spreading layers, each disposed on the p-type layer of each mesa;
a plurality of junction spacers comprising a dielectric material conformal to a portion of the sidewalls, and insulating the current spreading layer, the p-type layer, the active region, and an insulated portion of the n-type layer of each mesa from an n-contact material;
a plurality of active metal-semiconductor contacts electrically contacting the n-contact material and comprising an uninsulated portion of the n-type layer of each of the mesas along the sidewalls, the uninsulated portion of the n-type layer comprising a doped N-type material;
a plurality of cathodes comprising the n-contact material between each of the mesas, providing optical isolation therebetween; and
a plurality of anodes, each anode comprising one or more p-contact materials in contact with the current spreading layer.

2. The LED array of claim 1, wherein the junction spacers span a longitudinal distance of greater than or equal to 20% of the thickness of the semiconductor layers.

3. The LED array of claim 1, wherein the n-type layer comprises: the doped N-type material, and one or more regions of undoped or lesser-doped n-type material, wherein any doping content of the undoped or lesser-doped n-type material is less than a doping content of the doped N-type material and a first portion of the region of doped N-type material is located in the uninsulated portion of the n-type layer and a second portion of the region of doped n-type material is located in the insulated portion of the n-type layer.

4. The LED array of claim 3, wherein the doped N-type material is sandwiched between first and second regions of undoped or lesser-doped n-type material.

5. The LED array of claim 1, wherein the doped N-type material constitutes greater than or equal to 20% of the thickness of the semiconductor layers.

6. The LED array of claim 1, wherein the thickness of the semiconductor layers t₁ is in a range of from 1 μm to 10 μm, and/or the junction spacers have a thickness in a range of from 500 nm to 1 μm.

7. The LED array of claim 1, wherein the dielectric material of the junction spacers comprises a material selected from the group consisting of silicon dioxide (SiO₂), aluminum oxide (AlOₓ), silicon oxynitride (Si₂ON₂), and silicon nitride (Si₃N₄), and/or combinations thereof.

8. The LED array of claim 1, wherein the junction spacers comprise a layered structure effective as a distributed Bragg reflector (DBR).

9. The LED array of claim 8, wherein the junction spacers comprise a layered structure comprising one or more pairs of silicon dioxide (SiO₂) and titanium dioxide (TiO₂) layers or of silicon dioxide (SiO₂) and niobium pentoxide (NbO₅) layers.

10. A display comprising: the light emitting diode (LED) array according to claim 1 affixed to a device substrate by anode metallization bumps.

11. The display of claim 10 further comprising a sapphire substrate on which the semiconductor layers were grown.

12. The display of claim 10, wherein the pixels emit a single color.

13. The display of claim 10, wherein a first plurality of pixels is designed to emit a red color, a second plurality of pixels is designed to emit a blue color, and a third plurality of pixels is designed to emit a green color.

14. The display of claim 10 comprising: light emitting diodes (LEDs) having at least one characteristic dimension of less than or equal to 500 micrometers, the character dimension being selected from the group consisting of: height, width, depth, thickness, and combinations thereof.

15. A method of manufacturing a light emitting diode (LED) device, the method comprising:
growing a plurality of semiconductor layers including an n-type layer, an active region, and a p-type layer on a substrate; depositing a current spreading layer on the p-type layer;
depositing a mesa dielectric material on the current spreading layer;
etching the mesa dielectric material and forming inner spacers and deposing a p-contact layer;
etching the current spreading layer, the p-type layer, the active region, and a portion of the n-type layer, to form openings;
depositing a dielectric material conformally in the openings on exposed surfaces of the p-type layer, the active region, the portion of the n-type layer, the current spreading layer to form junction spacers that contact the current spreading layer, the inner spacers, the p-type layer, the active region, the portion of the n-type layer;
etching a remaining portion of the n-type layer to expose a top surface of the substrate to form trenches and to expose a doped N-type material, and thereby preparing a plurality of mesas defining pixels having sidewalls, and each of the mesas comprising the semiconductor layers having a thickness;
deposition of a hard mask material and forming anode sidewalls in the hard mask material, which with the top surface of the p-contact layer define hard mask openings;
depositing an electrode metal on the substrate filling the trenches and the hard mask openings; and
processing the substrate to remove excess electrode metal and to form an n-contact material providing optical isolation between each of the mesas, and electrically contacting the first portion of the doped N-type layer and the first n-type template layer of each of the mesas along the sidewalls, and to form a p-metal material in the hard mask openings.

16. The method of claim 15, wherein the semiconductor layers are grown on a substrate comprising sapphire, silicon carbide (SiC), silicon (Si), gallium arsenide (GaAs), or indium phosphide (InP).

17. The method of claim 15 further comprising depositing a passivation layer on the substrate, forming openings therein, and depositing anode metallization bumps over the passivation layer and in the openings of the passivation layer.

18. The method of claim 15, wherein the junction spacers span a longitudinal distance of greater than or equal to 20% of the thickness of the semiconductor layers.

19. The method of claim 15, wherein the dielectric material of the junction spacers comprises a material selected from the group consisting of silicon dioxide (SiO₂), aluminum oxide (Al₂O₃), silicon oxynitride (Si₂ON₂), and silicon nitride (Si₃N₄), and/or combinations thereof.

20. The method of claim 15, wherein the dielectric material of the junction spacers comprises a layered structure effective as a distributed Bragg reflector (DBR), preferably the junction spacers comprise a layered structure comprising one or more pairs of silicon dioxide (SiO₂) and titanium dioxide (TiO₂) layers or of silicon dioxide (SiO₂) and niobium pentoxide (NbO₅) layers.
